(19) United States
(12) Patent Application Publication
(10) Pub. No.: US 2024/0234840 A9
(43) Pub. Date: Jul. 11, 2024

(54) METHOD OF EARLY THERMAL RUNAWAY DETECTION BY INTERPRETING CELL-LEVEL CHARGING RESPONSE

(71) Applicant: GM Global Technology Operations LLC, Detroit, MI (US)

(72) Inventors: Ibrahim Haskara, Macomb, MI (US); Bharatkumar Hegde, Bloomfield Hills, MI (US); Chen-fang Chang, Bloomfield Hills, MI (US)

(21) Appl. No.: 17/969,034

(22) Filed: Oct. 19, 2022

(51) Int. Cl. H01M 10/44; H01M 10/48; H02J 7/00

(52) U.S. Cl. CPC H01M 10/443; H01M 10/486; H02J 7/00309; H02J 7/0047; B60L 58/24

(57) ABSTRACT

A vehicle, system and a method of predicting a thermal runaway event in a battery pack. The vehicle includes a battery pack having a plurality of battery cells. The system includes a sensor and a processor. The measures a parameter of a battery cell of a battery pack of the vehicle. The processor is configured to determine a charging response of the battery cell from the parameter, determine a likelihood of the thermal runaway event from the charging response, and control an operation of the vehicle to prevent the thermal runaway event based on the likelihood.

### INTRODUCTION

The subject disclosure relates to operation of a battery pack used in a vehicle and, in particular, to a system and method for predicting an onset of a thermal runaway event at the battery pack in order to be able to prevent the event from occurring.

A battery pack used in a vehicle includes a plurality of battery cells that provide electrical power to the vehicle. Thermal runaway can occur in the battery pack when a short circuit occurring in one battery cell generates heat that causes a short circuit in a neighboring cell, which generates additional heat, leading to a cascade of short circuits. Methods for detecting when a thermal runaway commences leaves little time for taking preventative measures. Accordingly, it is desirable to provide a method for predicting a thermal runaway event prior to its occurrence.

### SUMMARY

In one exemplary embodiment, a method of preventing a thermal runaway event in a battery pack is disclosed. A parameter of a battery cell of the battery pack is measured during charging of the battery pack. A charging response of the battery cell is determined from the parameter. A likelihood of the thermal runaway event is determined from the charging response. An operation of the battery pack is controlled to prevent the thermal runaway event based on the likelihood.

In addition to one or more of the features described herein, the parameter is at least one of a current, a voltage, and a temperature. The charging response is a charging rate of the battery cell. The method further includes determining the charging rate by performing at least one of determining a charging time for charging the battery cell over a pre-specified voltage range and determining a voltage spanned during a pre-specified time span. The method further includes determining the likelihood using one of an absolute threshold and a variational threshold. In an embodiment in which the parameter is a voltage, the method further includes determining a voltage-time area from a measurement of the voltage. The method further includes measuring the parameter during at least one of a constant voltage phase of a charging of the battery cell, a discharge phase of the battery cell, and a self-discharge when the battery pack is at rest.

In another exemplary embodiment, a system for preventing a thermal runaway event from occurring in a vehicle is disclosed. The system includes a sensor and a processor. The measures a parameter of a battery cell of a battery pack of the vehicle. The processor is configured to determine a charging response of the battery cell from the parameter, determine a likelihood of the thermal runaway event from the charging response, and control an operation of the vehicle to prevent the thermal runaway event based on the likelihood.

In addition to one or more of the features described herein, the parameter is at least one of a current, a voltage, and a temperature. The charging response is a charging rate of the battery cell. The processor is further configured to determine the charging rate by performing at least one of determining a charging time for charging the battery cell over a pre-specified voltage range and determining a voltage spanned during a pre-specified time span. The processor is further configured to determine the likelihood using one of an absolute threshold and a variational threshold. In an embodiment in which the parameter is a voltage, the processor is further configured to determine a voltage-time area from a measurement of the voltage. The processor is further configured to measure the parameter during at least one of a constant voltage phase of a charging of the battery cell, a discharge phase of the battery cell, and a self-discharge when the battery pack is at rest.

In yet another exemplary embodiment, a vehicle is disclosed. The vehicle includes a battery pack having a plurality of battery cells, a sensor for measuring a parameter of the battery cell, and a processor. The processor is configured to determine a charging response of the battery cell from the parameter, determine a likelihood of a thermal runaway event from the charging response, and control an operation of the vehicle to prevent the thermal runaway event based on the likelihood.

In addition to one or more of the features described herein, the parameter is at least one of a current, a voltage, and a temperature. The charging response is a charging rate of the battery cell and the processor is further configured to determine the charging rate by performing at least one of determining a charging time for charging the battery cell over a pre-specified voltage range and determining a voltage spanned during a pre-specified time span. The processor is further configured to determine the likelihood using one of an absolute threshold and a variational threshold. In an embodiment in which the parameter is a voltage, the processor is further configured to determine a voltage-time area from a measurement of the voltage. The processor is further configured to measure the parameter during at least one of a constant voltage phase of a charging of the battery cell, a discharge phase of the battery cell, and a self-discharge when the battery pack is at rest.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows a vehicle in accordance with an exemplary embodiment;

FIG. 2 shows a circuit diagram of a battery cell in an illustrative embodiment;

FIG. 3 shows a graph of cell voltage during a charging event for battery cells of having different levels of battery health;

FIG. 4 shows a graph illustrating a method of measuring a charging rate based on charging time over a pre-specified voltage range;

FIG. 5 shows a graph illustrating a method of measuring a charging rate based on a voltage range achieved during a pre-specified time span;

FIG. 6 shows a graph illustrating a method for smoothing voltage measurements to reduce the effects of cell voltage offset and noise;

FIG. 7 shows a flow chart of a method for determining a voltage during a charging event;

FIG. 8 shows a flow chart of a method for determining a discharge rate for the battery cell when the battery of vehicle is at rest;

FIG. 9 shows a graph of charging time for battery cells of different health under different charging parameters; and

FIG. 10 shows a flowchart of a method for predicting a thermal runaway event from a charging parameter.

### DETAILED DESCRIPTION

The following description is merely exemplary in nature and is not intended to limit the present disclosure, its application or uses. It should be understood that throughout the drawings, corresponding reference numerals indicate like or corresponding parts and features.

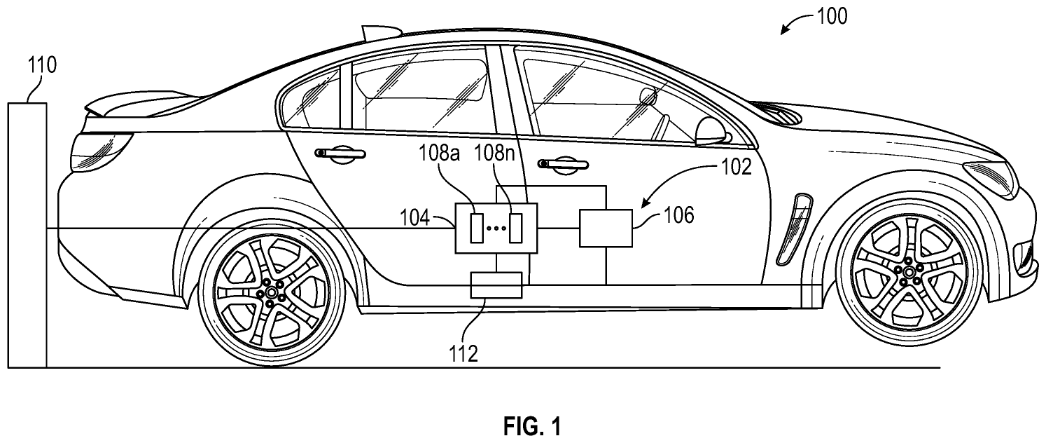

In accordance with an exemplary embodiment, FIG. 1 shows a vehicle 100. The vehicle 100 can be a hybrid vehicle, an electric vehicle, or any vehicle that operates off of a high voltage battery. The vehicle 100 includes an electrical system 102 including a battery pack 104 and one or more electrical loads 106 which operate using power provided by the battery pack. The battery pack 104 can include a plurality of battery cells 108a-108n and one or more sensors (not shown) that obtain measurements of parameters of the battery pack and battery cells. As shown in FIG. 1, the vehicle is plugged into a charging station 110 which charges the battery pack 104 and the battery cells 108a-108n.

The vehicle 100 further includes a controller 112. The controller 112 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. The controller 112 may include a non-transitory computer-readable medium that stores instructions which, when processed by one or more processors of the controller 112, implement a method of predicting a thermal runaway event and controlling operation of the vehicle 100, the electrical system 102, battery pack 104, battery cells 108a-108n and/or electrical loads 106, based on the prediction, and to send a warning signal or take preventative action, according to one or more embodiments detailed herein.

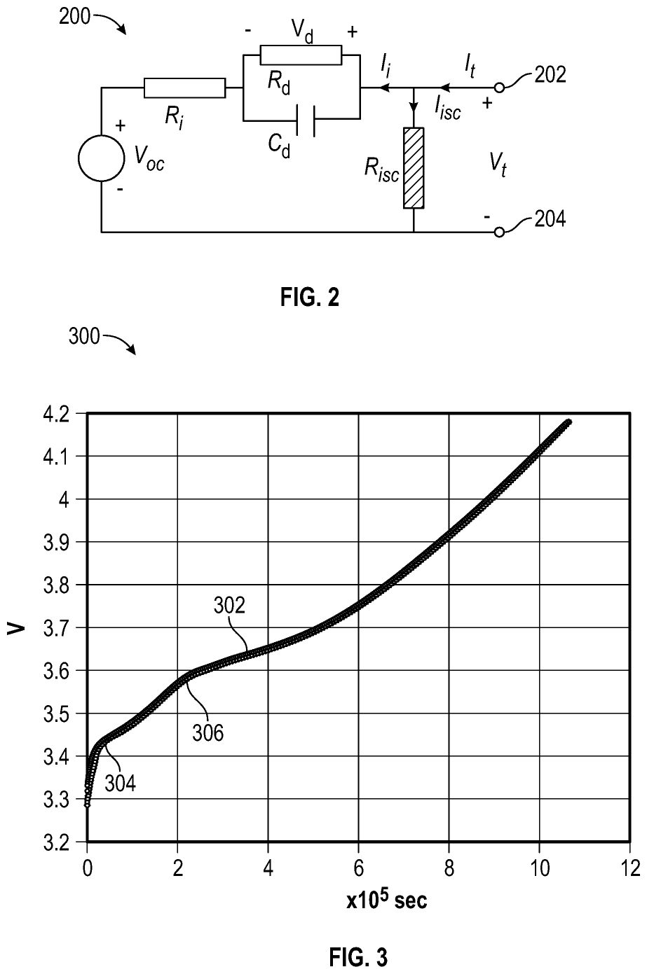

FIG. 2 shows a circuit diagram 200 of a battery cell in an illustrative embodiment. The circuit diagram 200 includes an open circuit voltage V_{OC} and an internal resistance Rᵢ of the battery cell. The battery cell includes a diffusion layer that introduces a diffusion layer voltage V_{d} based on a diffusion layer resistance R_{d} and a diffusion layer capacitance C_{d}. A voltage measurement V(t) of the battery cell can be taken across nodes 202 and 204. A short circuit resistance R_{isc} is shown between nodes 202 and 204. The short circuit resistance R_{isc} serves as a representation of an internal short of the battery cell, especially prior to a potential thermal runaway event. The internal short can be caused by many factors, such as cell anomalies, a torn anode, melting, etc. The location of the internal short can vary within the battery cell, and the magnitude of the internal short can change based on the health of the battery. When the battery cell is healthy and there is no short-circuit, the short circuit resistance R_{isc} is infinite (i.e., R_{isc}=∞). When there is a total short circuit, R_{isc}=0. The methods herein measure the short circuit resistance at levels before a total short circuit occurs.

An applied charging current Iₜ is shown being applied to the battery cell at node 202. An internal current L is related to the applied charging current It and a short current I_{isc} lost through a short in the battery cell by Kirchoff's Law, as shown in Eq. (1):

Iₜ=Iᵢ+I_{isc} Eq. (1)

The measured voltage Vₜ is related to the amount of internal current Iᵢ that enters into the battery cell, as shown by Eq. (2):

Vₜ=V_{oc}+RᵢₙₜIᵢ+V_{d} Eq. (2)

When there is no short-circuit, (i.e., R_{isc}=∞) the short current I_{isc} is zero and the internal current is equal to the applied charging current (i.e., Iᵢ=Iₜ). When there is a total short circuit (i.e., R_{isc}=0), the short current I_{isc} is equal to Iₜ and the internal current is zero (i.e., Iᵢ=0).

FIG. 3 shows a graph 300 of cell voltage during a charging event for battery cells of having different levels of battery health. Time is shown along the abscissa (in 10⁵ seconds) and cell voltage is shown along the ordinate axis in volts (V). Three charging curves are shown of illustrative purposes. A first charging curve 302 shows the charging of a fully healthy battery cell with no short-circuit (e.g., R_{isc}=∞). A second charging curve 304 shows the charging for a first faulty battery cell. The short-circuit resistance indicates the health of the battery cell. For the first faulty battery, the short-circuit resistance (e.g., R_{isc}=100Ω) indicates that a thermal runaway event is possible. A third charging curve 306 shows the charging for a second faulty battery cell. Since the short-circuit resistance (e.g., R_{isc}=10Ω) of the second faulty batter cell is less than for the first faulty battery cell, a thermal runaway even is even more likely. Various charging responses can be measured with respect to these curves. A charging response can be a charging rate, in an embodiment.

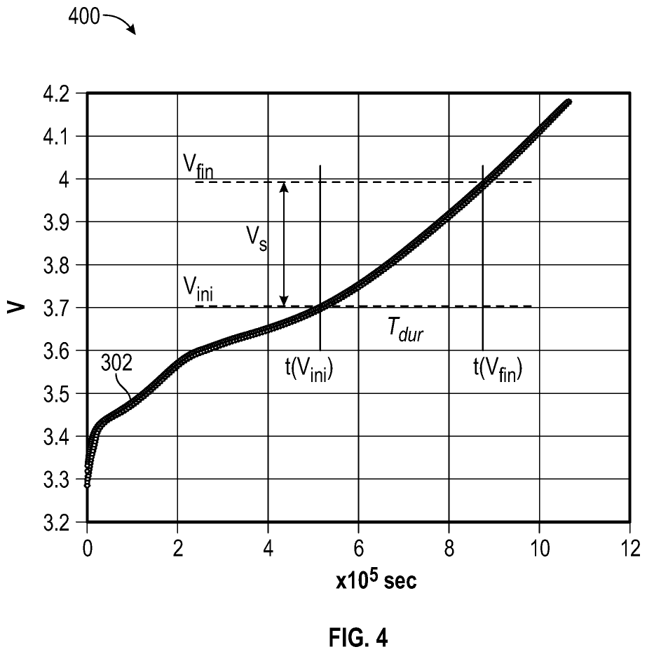

FIG. 4 shows a graph 400 illustrating a method of measuring a charging rate based on charging time over a pre-specified voltage range. Time is shown along the abscissa in seconds (in 10⁵ seconds) and cell voltage is shown along the ordinate axis in volts (V). First charging curve 302 from FIG. 3 is shown for illustrative purposes. To obtain a charging time, first a voltage range Vₛ is pre-specified. The voltage range Vₛ is bound at its lower end by a first voltage (Vᵢₙᵢ) and at its upper end a second voltage (V_{fin}). The cell voltage is monitored during charging. A first timestamp is recorded when the cell voltage rises above the first voltage Vᵢₙᵢ. A second timestamp is recorded when the cell voltage rises above the second voltage V_{fin}. The time duration ΔT for charging over the pre-specified range is determined from the first timestamp and the second timestamp. (i.e., ΔT_{dur}=t_{fin}−tᵢₙᵢ). A charging rate can then be determined using the pre-specified voltage range Vₛ and the time duration ΔT.

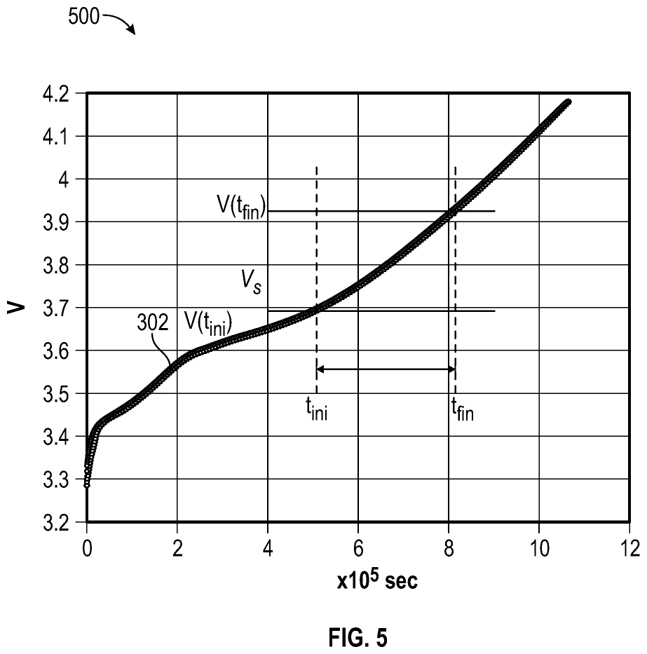

FIG. 5 shows a graph 500 illustrating a method of measuring a charging rate based on a voltage range achieved during a pre-specified time span. Time is shown along the abscissa (in 10⁵ seconds) and cell voltage is shown along the ordinate axis in volts (V). First charging curve 302 from FIG. 3 is shown for illustrative purposes. To measure the voltage range, a time span ΔT is first pre-specified. The time span ΔT is defined between a first time tin, and a second time t_{fin}. During charging, voltage is measured at a plurality of time intervals δt over the pre-specified time span ΔT. A first voltage Vᵢₙᵢ is recorded when the charging time first exceeds the first time tin, and the final voltage V_{fin} is recorded when the charging time first exceeds the second time t_{fin}. The voltage spanned Vₛ during the time span is determined from these voltages (Vₛ=V_{fin}−Vᵢₙᵢ). A charging rate can be determined for the battery cell using Vₛ and the time duration ΔT.

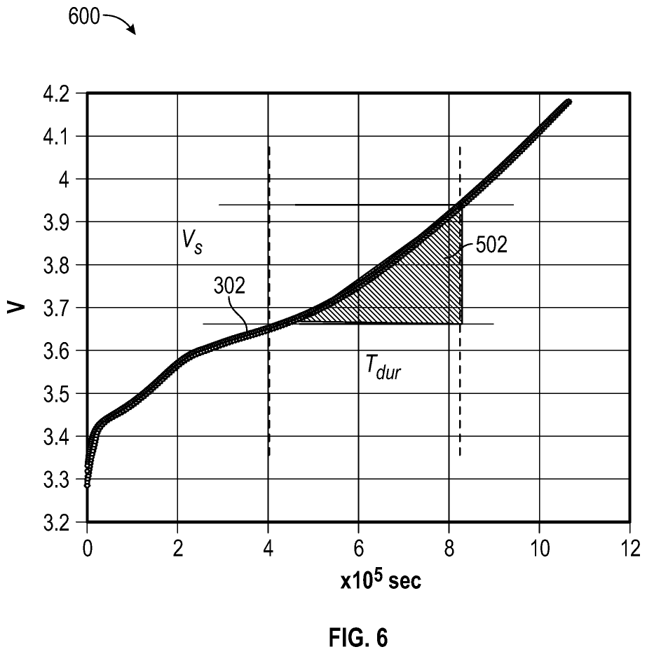

FIG. 6 shows a graph 600 illustrating a method for smoothing voltage measurements to reduce the effects of cell voltage offset and noise. For illustrative purposes, the measurements obtained using the method of a pre-specified time span. However, the methods disclosed herein can be used with the method of a pre-specified voltage span or other parameters. Voltage measurements Vᵢ(t) are obtained at time intervals δt until the pre-specified time span is completed. Once all voltage measurements Vᵢ(t) have been obtained, they are processed to determine a smoothed and offset-corrected voltage V(t) using Eq. (3):

$$V ( t ) = \frac{{\sum }_{over ( t - {t}_{ini} )} ( {V}_{i} ( t ) - {\overline{V}}_{i , ini} ) \cdot δ t}{t - {t}_{ini}} \qquad Eq . ( 3 )$$

where V̅_{i,ini} is an initial voltage reading at the beginning of the time span (tᵢₙᵢ).

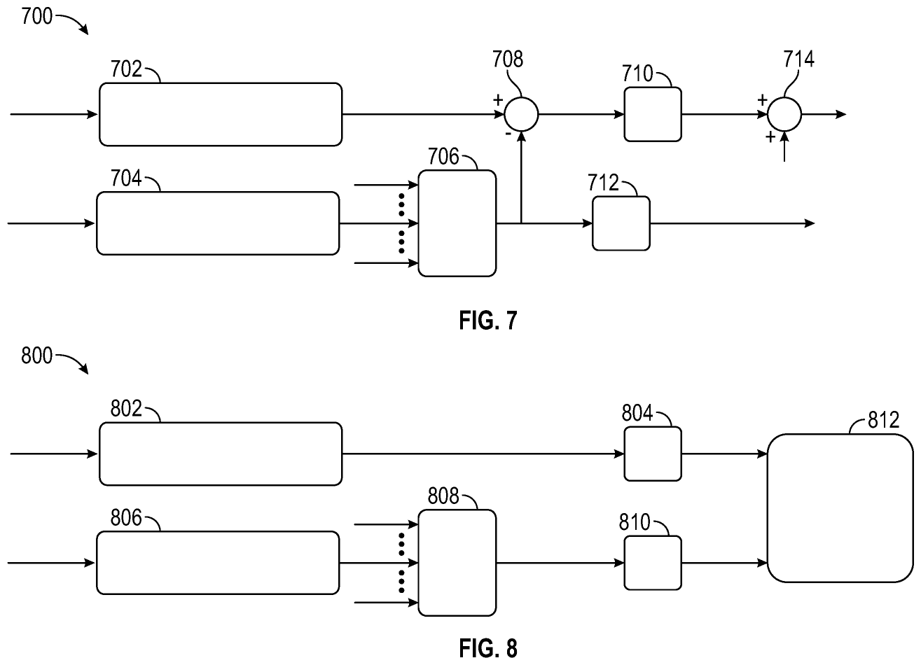

FIG. 7 shows a flow chart 700 of a method for determining a voltage V(t) during a charging event. In box 702, the voltage measurements Vᵢ(t) for a selected battery cell are received and a voltage-time area Aᵥᵢ(t) is determined from the voltage measurements Vᵢ(t), using Eq. (4):

Aᵥᵢ(t)=Σₒᵥₑᵣ₍ₜ₋ₜ_{ᵢₙᵢ}₎(Vᵢ(t)−V̅_{i,ini})·δt Eq. (4)

In box 704, voltage measurements for a group of battery cells of the battery pack (N battery cells) are received and the voltage-time areas Aᵥⱼ(t) are determined for each of the plurality of battery cells using Eq. (4). In box 706, an average voltage-time area is calculated for the N battery cells, as shown in Eq. (5):

$${A}_{v , ave} ( t ) = \frac{1}{N} \sum {A}_{vj} ( t ) \qquad Eq . ( 5 )$$

At summer 708, a difference is determined between the voltage-time area for the selected battery cell and the average-voltage time area, thereby obtaining a differential area ΔAᵥ(t). In box 710, the differential area is converted into a differential voltage ΔVₛ(t). The conversion includes multiplying the differential area by a multiple g and dividing by the time span ΔT, as shown in Eq. (6):

$${ΔV}_{s} ( t ) = Δ {A}_{v} ( t ) \cdot \frac{g}{Δ T} \qquad Eq . ( 6 )$$

In box 712, the average voltage-time area A_{v,ave}(t) is converted into an average voltage Vₐᵥ(t). At summer 714, the average voltage and the differential voltage are added to determining the voltage span Vₛ(t). All of the variables are computed continuously and are available to be sampled and interpreted in various ways. Areas Aᵥᵢ(t) and ΔAᵥ(t) can be used to capture variations in voltage response at every time step. ΔVₛ(t) and ΔT are computed at every sampling interval, and their ratio (ΔVₛ(t)/ΔT) is related to a magnitude of an internal short (i.e., R_{isc}).

During charging, the charge current is usually high at first and reduces over time as the charging continues. When the battery cell is almost charged, charging enters a constant voltage phase in which the charge current becomes very small to offset the resistive losses, thereby maintaining a constant voltage. The methods disclosed herein can be performed during any segment of charging, during a constant voltage phase and when the battery cell is at rest, as discussed with respect to FIG. 8.

FIG. 8 shows a flow chart 800 of a method for determining a discharge rate for the battery cell when the battery of vehicle is at rest. During rest, in which there is no charging current, a battery cell will naturally undergo a self-discharge. However, a battery cell with an internal short will experience a greater self-discharge than a healthy battery cell. In box 802, the voltage measurements Vᵢ(t) are received for a selected battery cell and used to output a voltage-time area Aᵥᵢ(t) for the battery cell. The voltage measurements are obtained over measurement intervals δt. The voltage measurements are used to determine an average initial voltage V̅_{i,ini}, which is used to create the area using Eq. (4). In box 804, the voltage-time area is divided by the total time ΔT and multiplied by a multiple g, using Eq. (6). In box 806, the areas are determined from each of the other battery cells of the battery pack. In box 808, the areas are used to determine an average area, using Eq. (5). In box 810, an average voltage drop is obtained by dividing the average voltage-time area by the total time ΔT and multiplying by a multiple g. In box 812, the voltage drop for the selected battery cell is compared against the average voltage drop for the battery pack in order to determine a likelihood of a short or which can lead to a thermal runaway event. While discussed with respect to a self-discharge phase, the method can be also using during any discharge phase for the battery cell such as during operation of the vehicle.

Using the area under a voltage curve method, the area under a voltage curve for a healthy battery cell will be approximately zero during rest, since the discharge rate is slow and related voltage curve is substantially horizontal over time. The area under the voltage curve for an unhealthy battery cell will be non-zero, such the discharge rate is faster and thus the related voltage curve decreases with time. The magnitude of the area will be indicative of the rate of decay of the unhealthy battery cell, which is directly related to the magnitude of the internal short within the unhealthy battery cell.

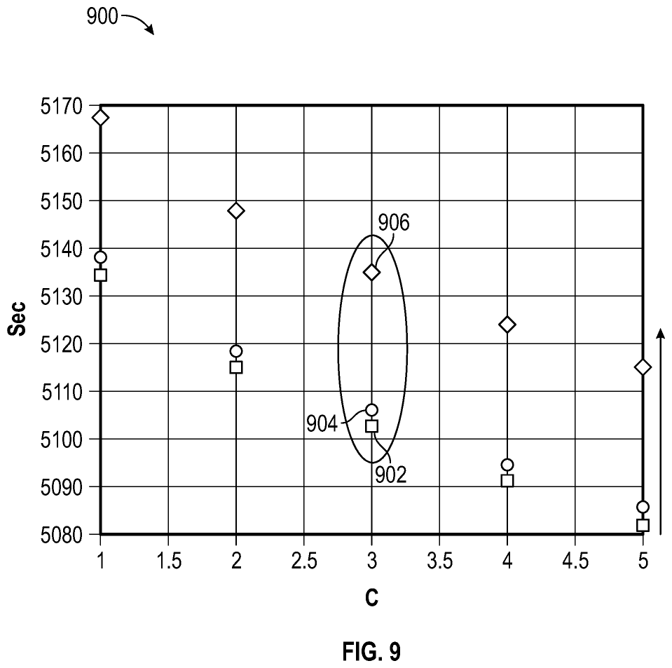

FIG. 9 shows a graph 900 of charging time for battery cells of different health under different charging parameters. The charging time for a battery cell can be directly related to the short-circuit resistance of the battery cell. The longer the time needed to charge the battery cell, the worse the health the battery cell is in. Different case numbers are indicated along the abscissa and time is shown in seconds along the ordinate axis. Each case number indicates a different charging condition for the battery cell, such as different charging voltage, different charging current, different charging temperatures, different charging resistances, etc. Case #3 is selected for illustrative purposes. The charging time 902 a healthy battery cell (R_{isc}=∞) is about 5120 seconds. The charging time 904 for the first faulty battery cell (R_{isc}=100Ω) is about 5150 seconds. The charging time 906 for the second faulty battery cell (R_{isc}=10Ω) is about 5135 seconds. The charging times shown in FIG. 9 can be used to predict a likelihood of a thermal runaway event. Although FIG. 9 shows charging times, a similar chart can be made showing voltage spans obtained during a pre-specified time span.

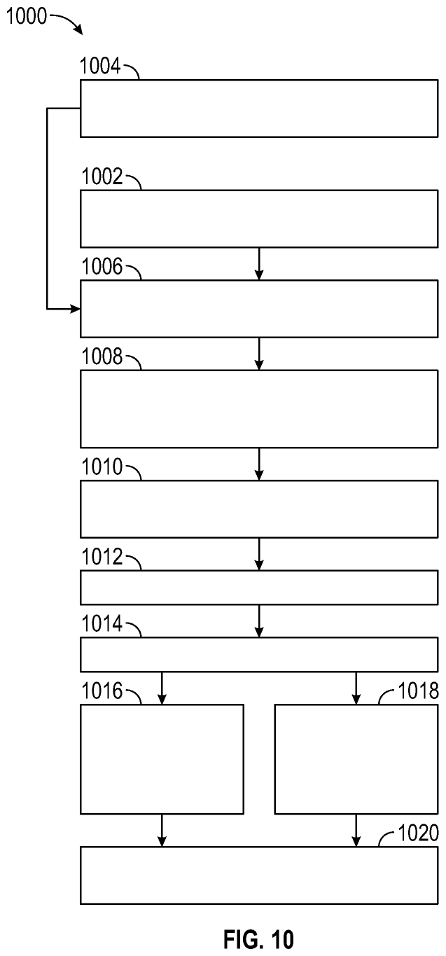

FIG. 10 shows a flowchart 1000 of a method for predicting a thermal runaway event from a charging parameter. For the flowchart 1000, the charging parameter is selected as voltage. However, it is to be understood that the charging parameter can be time, current, temperature, etc., in alternate embodiments. In box 1002, individual charging conditions, such as cell voltages and current profiles, are obtained at a time prior to a charging event. In box 1004, a charging event or scenario is established, such as by plugging the vehicle into a charging station. In box 1006, a measurement scenario, such as using a pre-selected time span, is selected and relevant parameters (e.g., ΔT, tᵢₙᵢ, t_{fin}, Areas) are established.

In box 1008, relevant voltage measurements are obtained. The measurements are obtained at timer intervals δt. Compensation for noise and voltage offset can be performed at this time. Voltage measurements can be obtained for the selected battery cell and the group of N battery cells. In box 1010, the relevant parameters (e.g., ΔVₛ, areas A) are extracted from the measurements. The parameters can be obtained for the selected battery cell and the group of N battery cells. In box 1012, post-conditioning of the parameters is performed. Post-conditioning can include fusing parameter results over multiple events and charging scenarios. In box 1014, the voltages are mapped to a likelihood rank predictive of thermal runaway. The likelihood rank can then be used to predict a thermal runaway event by comparing the likelihood rank to either a variational standard (box 1016) or an absolute standard (box 1018).

In box 1016, a variational standard is used to predict a thermal runaway event. The likelihood rank for the battery cell and likelihood ranks for the battery pack (or N battery cells) are obtained. The group likelihood ranks are used to establish a mean likelihood and a variational threshold with respect to the mean likelihood. The likelihood rank for the battery cell is compared to the variational threshold to predict a thermal runaway event and generate a warning signal.

In box 1018, an absolute standard is used to predict a thermal runaway event. An absolute threshold can be established based on segment length, voltage range, charging current and temperature. The likelihood rank for the battery cell is compared to the absolute threshold to determine predict a thermal runaway event and generate a warning signal.

In box 1020, the warning signal is output to a driver or user of the vehicle. In addition, preventive actions can be taken, such as ending the charging process, disconnecting the battery pack, isolating a battery cell that is at high risk, etc.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method of preventing a thermal runaway event in a battery pack, comprising:
measuring a parameter of a battery cell of the battery pack during charging of the battery pack;
determining a charging response of the battery cell from the parameter;
determining a likelihood of the thermal runaway event from the charging response; and
controlling an operation of the battery pack to prevent the thermal runaway event based on the likelihood.

2. The method of claim 1, wherein the parameter is at least one of: (i) a current; (ii) a voltage; and (iii) a temperature.

3. The method of claim 1, wherein the charging response is a charging rate of the battery cell.

4. The method of claim 3, further comprising determining the charging rate by performing at least one of: (i) determining a charging time for charging the battery cell over a pre-specified voltage range; and (ii) determining a voltage spanned during a pre-specified time span.

5. The method of claim 3, further comprising determining the likelihood using one of: (i) an absolute threshold; and (ii) a variational threshold.

6. The method of claim 1, wherein the parameter is a voltage, further comprising determining a voltage-time area from a measurement of the voltage.

7. The method of claim 1, further comprises measuring the parameter during at least one of: (i) a constant voltage phase of a charging of the battery cell; (ii) a discharge phase of the battery cell; and (iii) a self-discharge when the battery pack is at rest.

8. A system for preventing a thermal runaway event from occurring in a vehicle, comprising:
a sensor for measuring a parameter of a battery cell of a battery pack of the vehicle;
a processor configured to:
determine a charging response of the battery cell from the parameter;
determine a likelihood of the thermal runaway event from the charging response; and
control an operation of the vehicle to prevent the thermal runaway event based on the likelihood.

9. The system of claim 8, wherein the parameter is at least one of: (i) a current; (ii) a voltage; and (iii) a temperature.

10. The system of claim 8, wherein the charging response is a charging rate of the battery cell.

11. The system of claim 10, wherein the processor is further configured to determine the charging rate by performing at least one of: (i) determining a charging time for charging the battery cell over a pre-specified voltage range; and (ii) determining a voltage spanned during a pre-specified time span.

12. The system of claim 8, wherein the processor is further configured to determine the likelihood using one of: (i) an absolute threshold; and (ii) a variational threshold.

13. The system of claim 8, wherein the parameter is a voltage, wherein the processor is further configured to determine a voltage-time area from a measurement of the voltage.

14. The system of claim 8, wherein the processor is further configured to measure the parameter during at least one of: (i) a constant voltage phase of a charging of the battery cell; (ii) a discharge phase of the battery cell; and (iii) a self-discharge when the battery pack is at rest.

15. A vehicle, comprising:
a battery pack having a plurality of battery cells;
a sensor for measuring a parameter of the battery cell;
a processor configured to:
determine a charging response of the battery cell from the parameter;
determine a likelihood of a thermal runaway event from the charging response; and
control an operation of the vehicle to prevent the thermal runaway event based on the likelihood.

16. The vehicle of claim 15, wherein the parameter is at least one of: (i) a current; (ii) a voltage; and (iii) a temperature.

17. The vehicle of claim 15, wherein the charging response is a charging rate of the battery cell and the processor is further configured to determine the charging rate by performing at least one of: (i) determining a charging time for charging the battery cell over a pre-specified voltage range; and (ii) determining a voltage spanned during a pre-specified time span.

18. The vehicle of claim 15, wherein the processor is further configured to determine the likelihood using one of: (i) an absolute threshold; and (ii) a variational threshold.

19. The vehicle of claim 15, wherein the parameter is a voltage, wherein the processor is further configured to determine a voltage-time area from a measurement of the voltage.

20. The vehicle of claim 15, wherein the processor is further configured to measure the parameter during at least one of: (i) a constant voltage phase of a charging of the battery cell; (ii) a discharge phase of the battery cell; and (iii) a self-discharge when the battery pack is at rest.
